(19) United States
(12) Patent Application Publication
(10) Pub. No.: US 2021/0116637 A1
(43) Pub. Date: Apr. 22, 2021

(54) Si Photonic Platform and Photonic Interposer

(71) Applicants: Dong Li, San Ramon, CA (US); Ge Yi, San Ramon, CA (US)

(72) Inventors: Dong Li, San Ramon, CA (US); Ge Yi, San Ramon, CA (US)

(21) Appl. No.: 16/658,103

(22) Filed: Oct. 20, 2019

(51) Int. Cl. G02B 6/12; G02B 6/122; G02B 6/13

(52) U.S. Cl. CPC G02B 6/12004; G02B 6/1223; G02B 6/13; G02B 2006/12121; G02B 2006/1205; G02B 2006/12061; G02B 2006/12038; G02B 2006/1204; G02B 2006/12054; G02B 2006/12123

(57) ABSTRACT

A CMOS compatible material platform for photonic integrated circuitry is invented. The material platform has SiO2 as cladding material, at least a bottom layer made of moderate refractive index material(s) fabricated first on a unpatterned SOI wafer, a bonded system substrate, a set of photonic circuitry made within a SOI layer of the SOI wafer after its substrate and BOX layer removed, and some coupling devices enabling light travelling between the devices made within these two layers. A solution to provide IIIV laser diodes boned and embedded in the system substrate is also proposed. The invention provides a great material platform to offer full set of photonic building blocks for all sort of different applications such as photonic circuitry for optical neural network, quantum computing, telecommunication, data communication, optical switching, optical sensing, passive and/or active Si optical interposer with its size even bigger than lithography step field size.

### FIELD OF INVENTION

The invention is related to material platform and process integration solutions for large scale CMOS compatible photonic integrated circuits. Particularly, to use wafer-to-wafer bonding to vertically integrate heterogeneous optical material layers/devices on a single wafer substrate with medium refractive index optical material close to substrate. There are also optical coupling paths between the photonic circuitries made in different material layers.

### BACKGROUND ART

Photonic integrated circuit starting from telecommunication has been expanding its applications in many areas: photonic artificial neural network chips for AI; photonic chips for quantum computation; photonic chips for data processing for RF/microwave; large scale optical switches and routers; large size active or passive optical interposer for photonic and electronic mixed (or hybrid) neural network chip or quantum computing chip; highly integrated optical sensor with multiple optical sensors targeted for different sensing functions.

In view of the above mentioned new chips with the applications in new areas, there is a trend to make the size of the photonic chips larger due to many technical reasons. For example, larger photonic chips can have more neurons and synapsess, which can handle much more complicated calculations while large optical interposer to allow more electronic chips on it to be connected optically.

There are many material platforms for photonic chips, such as III-V semiconductor based (e.g. InP-based); Silicon over insulator (SOI) based; diamond on insulator based; LiNbO3 based platforms. All these material platforms have developed many optical building blocks (or devices) on its own and each platform has it own merits and disadvantage. Unfortunately, none of platforms have a comprehensive set of needed building blocks with the best performance, energy efficiency, and cost saving to offer design engineers a sweetest solution to meet the needs for all photonic circuit designs.

Among above mentioned platforms, the CMOS compatible ones, particularly SOI platform, has the most potentials due to the fact that they use CMOS compatible process, which offers well developed fabrication process technologies, robust reliability, a low cost volume manufacture path.

SOI platform is also, by far, the most well developed CMOS compatible material platform. Even the III-V light source has been successfully integrated in this platform at the CMOS front end of line (FEOL) by Intel in volume production, let alone passive optical components, such as splitters, filters, (de)multiplexers (based on Mach-Zahnder interferometer (MZI)), polarization handling components, interferometers, resonators, edge or grating coupling structures to optical fibers; and active optical components, such as high speed modulator (MZI or ring resonator based), high speed photodiode based on Ge epi-growth on Si, slow speed electrically driven micro-heaters.

However, SOI platform also has its own shortcomings. Firstly, Si is a indirect bandgap materials, therefore it is not easy to generate needed light source in Silicon; Secondly, due to the large refractive index contrast between Si (−3.5) and SiO2 (−1.5), the optical loss and phase of the light is very sensitive to any fabrication error during wafer processes. As such, it is very hard to develop complicated passive (de)multiplexers such as arrayed waveguide grating (AWG), or planar concave grating (PCG) in SOI platform; Thirdly, due to Si waveguide for single optical mode has width below one microns meter, to extend the optical circuit larger than the lithography step field size the stitch error between the step fields can generate some overlay errors, which generates unintended bounced wave to disturb the coherence and optical phase. On the other hand, the coherence and optical phase maintenance are extremely important for coherent optic chips like those used in photonic artificial neural networks and quantum computing; Fourthly, although silicon have low absorption losses in the wavelength range from 1.1 μm (band edge of silicon) to about 3.7 μm (onset of mid-IR absorption of silica), for applications requiring shorter wavelengths (e.g. data communication at 850 nm, sensors operating in the therapeutic window etc.), silicon waveguide is not an great option; Fifthly, silicon has two photo absorption (TPA) related to Kerr effects, therefore, it has power limitation; Moreover, the large refractive index contrast also make the mode expansion is no that easy, alignment and coupling efficiency is not as good as the medium refractive contrast system such as silicon nitride (core)/silicon oxide (cladding) system when coupling to optical fiber(s).

Optical core materials whose refractive index below 3.0 provide a moderate (or medium) refractive index contrast against silicon oxide (refractive index (n) of 1.5) while comparing high refractive index SOI system. The moderate refractive index material (defined here as its refractive index n<3.0) core materials gives these core/cladding systems (such as Si3N4(n˜2.0)/SiO₂; SiNO (n˜1.8)/SiO₂; AlN(n˜2.14)/SiO₂; diamond(n˜2.4)/SiO₂; LiNbO3 (n˜2.16)/SiO₂; SiC(n˜2.6)/SiO2; Ta2O5 (n˜2.1)/SiO₂; TiO2(n˜2.5)/SiO₂; Si3N4/SiO₂/Si3N4(composite core)/SiO2 cladding; As2S3(n˜2.5)/SiO₂; high index doped SiO2 hydex(n˜upto 1.9)/SiO₂; and composite core using the combination of the above mentioned core materials/SiO2 cladding), beter manufacturability, generally lower optical loss together with some unique linear or nonlinear functionality, such as fluorescence light generation capability like those color centers in the diamond based systems.

It has been a long effort to try to fully integrated the moderate refractive contrast system into existing SOI platform. One typical example is the effort of integrating silicon nitride, which has much less temperature sensitive (much lower thermo-optic co efficiency), lower nonlinear effects, much higher power limitation, more tolerance to fabrication error (i.e. wavguide length/width, gaps between the light paths) and edge roughness, into the existing SOI platform for passive (de)multiplexers. In the all cases, the silicon nitride is deposited above the SOI. In other words, the SOI wafer is used as substrate, after optical circuit is created in SOI, the SiN, not in stoichiometry though, is deposited either by PECVD or PVD on top of SOI circuit (hereby, we name it as SOI-patterning-first-approach). This integration approach has a few major disadvantages: 1) due to the SOI circuit particularly the implantation already in place as well as Ge epi-growth over Si for photodiode (Ge PD), the deposition temperature for addon new materials such as SiN has some tight thermal budget limitation to avoid implanted ions' diffusion or existing Ge PDs damage. Therefore, stoichiometric Si3N4 can not be obtained; 2) the addon material changes the process and integration scheme of electric connection processes for Ge photodiode (for PECVD SiN) or existing active devices in the SOI layer. All these bring some hard technology and process limitations. For example, the SiN integrated in such a way can not be used to build passive (de)multiplexers with performance matching those build in stoichiometric Si3N4 deposited by Low Pressure Chemical Vapour Deposition (LPCVD) at high temperature (>700 C) followed by high-than-1000 C annealing for removing N—H and Si—H bonds, which has high optical absorption around 1520 nm. Apart from SiN, other CMOS compatible material systems, such as CVD/PECVD diamond, which is very important for quantum computing also need high temperature plasma processes. As such, SOI-patterning-first-approach can not offer a good material properties for diamond based optical circuit and its particular functionality.

Successfully integrated high quality moderate refractive material with Si nano waveguide based photonic circuits similar to what has been achieved in SOI platform can provide huge advantages in various existing key technology areas and also open a lot of possibilities for Si photonics technology. We can easily name a few here. For example, the Si3N4 integration providing much large power limitation makes its a great opportunity for artificial neural network linear section, which provides necessary power needed for subsequent nonlinear portion. Si3N4 integration also provide passive (de)multiplexers such as arrayed waveguide grating (AWG), or planar concave grating (PCG), which is extremely useful for telecommunication/data communication as well as artificial photonic neural network for artificial intelligence (AI). The integrated diamond material and photonics circuit before Si nanowaveguide can provide a full set of build blocks for photonics-based quantum computer. Integrated diamond or Si3N4 materials, which is less sensitive to fabrication error as well as stitch error cross lithography step fields, can extend photonic circuitry larger than the existing size of lithography step field. This makes the active or passive photonic interposor larger than lithography step size becomes possible, which will be very useful to have more electronic control chips on tops for much more complicated photonic switches for data center, photonic and electric hybrid neural network and quamtum computer, and high performance computer (HPC). It can even enable to realize the concept of HPC on a chip with optical connection to the external systems, which will dramatically reduce the size of super computer.

### SUMMARY OF THE INVENTION

In this invention, we proposed a heterogeneously integrated material platform, compatible to CMOS fabrication techniques, to overcome the above mentioned SOI shortcomings so that we could offer a full set the building blocks with best performance from individual material platforms.

The concept of the invention is a wafer-to-wafer-bonding enabled silicon-over-insulator (SOI)-layer-patterning-last approach. In details, starting with a silicon over insulator (SOI) wafer as the initial substrate, without patterning SOI layer, at least one layer of moderate refractive index material is deposited, along with post deposition annealing if needed, then patterned with optical circuitry first within this layer. Then through wafer to wafer bonding, a Si wafer is bonded as the final system substance while removing the substrate and buried oxide (BOX) layer of original SOI wafer to access the SOI layer for the creation of photonic circuitry within the SOI layer. The though silicon via (TSV) process can be introduced in the backend end of line (BEOL) during metal trace process as a TSV middle approach. Although the extra SiO2 cladding thickness makes the TSV process more challenging, since the TSV structure here is used mostly only as power supply lines and for thermal dissipation purpose, the aspect ratio of the TSV can be much smaller or the size of the TSV can be much larger than normal TSV in the electronic chips. This helps to ease the process challenges due to the SiO2 thickness increase for such an integration scheme.

The proposed approach provides the best quality for the moderate refractive index material due to lack of the process limitation. The photonic circuit in the layer of moderate refractive index material can include those links between the lithography step field and the structure for fiber coupling as well as the coupling structures enabling light travelling between the devices within the different layers of materials through evanescence coupling with mode size matching.

Since the thickness of SiO2 to system substrate is mostly decided by the SiO2 oxide thickness on the both side of the bonded interface, this is very flexible compared with BOX thickness on a SOI wafer. Similarly, the substrate resistance for system can be chosen based on the bonded wafer as the system substrate. This will provide much more freedom to the optical system designers. Moreover, the IIIV gain materials or even the fully functional laser diode can be bonded on the system substrate as a light source after it gets thinned down with proper mechanical stops at the interface between the substrate and SiO2.

With such a comprehensive heterogeneously integrated photonic material platform, multiple materials with their own merits can be used by designers for the best optical performance, lowest optical loss, and special functionality, which could be unique for a particular material. By doing so, we could build very complicated photo system to meet the challenges for photonic artificial neural network, quantum computer, large scale optical switch, larger than lithography step field passive and active photonic interposer for various applications.

### BRIEF DESCRIPTION OF THE DRAWINGS

FIG. 1 an embodiment of a finished device with two layers of moderate refractive index materials integrated below single crystalline Si layer with TSV structures revealed after the substrate thinning.

FIG. 2 an embodiment of an active photonic interposer with electronic chips and a laser diode as a light source, which are all flip chip boned on top the interposer.

FIG. 3(a)-(j) an embodiment of a process flow to make the structure shown in FIG. 1 starting with a SOI wafer.

FIG. 4(a)-(e) an embodiment of a process flow to integrate IIIV light source either through grating coupling or evanescence coupling in the substrate of the system.

### DETAILED DESCRIPTION

The following numerous specific detail descriptions are set forth to provide a thorough understanding of various embodiments of the present disclosure. It will be apparent to one skilled in the art, however, these specific details need not be employed to practice various embodiments of the present disclosure. In other instances, well known components or methods have not been described.

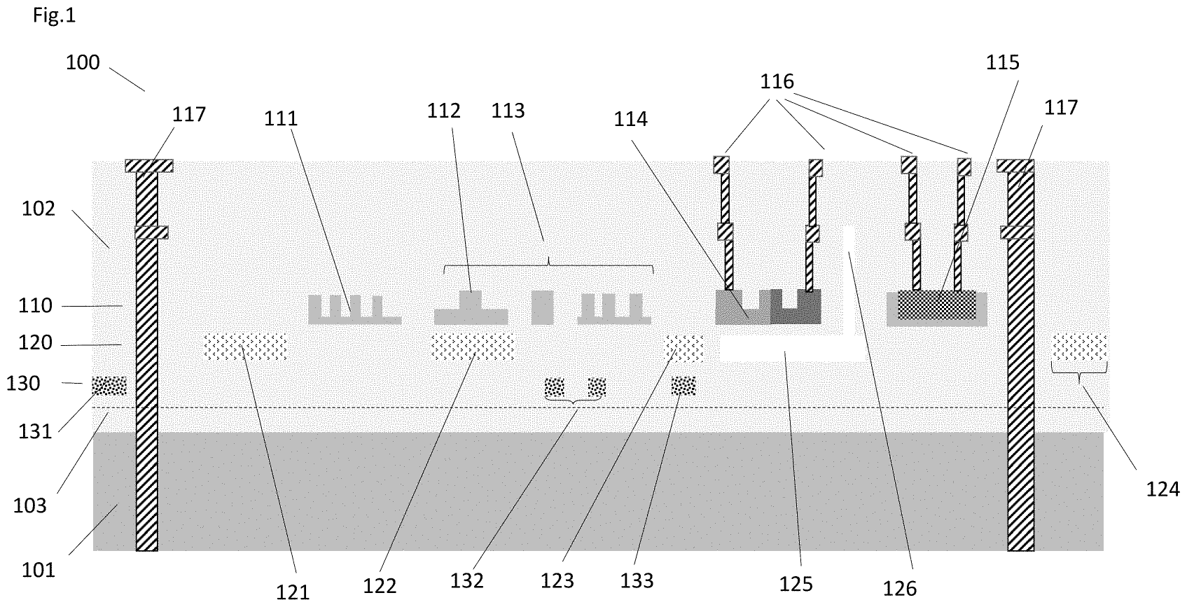

FIG. 1 shows a schematic cross section of a finished wafer system 100 with two layers of moderate refractive index material integrated below single crystalline Si layer. The system 100 has a Si substrate 101, on which SiO2 102 acts as cladding materials for various photonic circuitries. The dashline 103 represents the dielectric-to-dielectric bonding interface, which indicates the fact that all the features above the dashline 103 is bonded on top of the substrate 101. For drawing simplicity, the bond interface 103 shown here is between SiO2 and SiO2 but they can be other materials. There are three layer of materials: 110 represents the single crystal Si layer; 120 represents a layer of moderate refractive index material, while 130 stands for a layer of another moderate refractive index material, which is different from the material used in layer 120. Within single crystal Si layer 110, there are phtotonic circuitry made of various optical building blocks such as grating structure 111, different optical waveguide 112, 113, modulator 114, epitaxially grown Ge photodiode 115. For active device 114, and 115, there are also various electrical connections 116 to them. Moreover, there are also Through Silicon Via (TSV) structures 117 built in. The TSVs shown here are TSV middle structures, i.e. the TSV is made at the middle end of the line (MEOL) during wafer build such as just before the 1^{st} layer of Cu layer is made. Below layer 110, within layer 120, there are also photonic circuitry made of various passive optical features such as different waveguide or devices 121, 122, 123, 124. There is also a void structure 125, which was a sacrificial structure within layer 120 initially but later etched away to create a undercut structure below the device 114 during wafer build via a etch path 126. It is worthwhile to mention that the optical coupling between the build block 112 and feature 122 allows light passes between the photonic path in layer 110 and the optical circuitry in layer 120 through evanescence coupling with optical mode size matching. Also the feature 124 is crossing the lithographic step field to allow the optical circuitry extend larger than the lithographic step field if needed, for example, in the case of large photonic interposer. Having the cross step field optical component inside the layer of the layer 120 or 130 with moderate refractive index material has advantage of reducing the impact of stitching error between the lithographic step field on the light propagation as the features width in the moderate refractive index material have larger laterial dimensions than those in the single crystal Si layer for keeping single optical mode inside the waveguide structure. Of course, feature 124 can also represents an edge coupler with mode size expansion to enable the light couple to the external optical fiber. Nevertheless, when feature 124 is used for different purpose, its design have to vary.

In layer 130. there are also optical circuitry made of different optical devices shown as 131, 132, 133. Light can also travel between the photonic circuitries within layer 120 and 130 through the coupling structure comprised of 123 in layer 120 and 133 in layer 133 through evanescence coupling and mode size matching. Feature 131 can represent the optical device cross the lithographic feature step as feature 124 within layer 120.

The TSV structures 117 establish electrical connection through the whole system, which allows the power as well as electrical signal connection if needed through the substrate 101 to the front surface of the system.

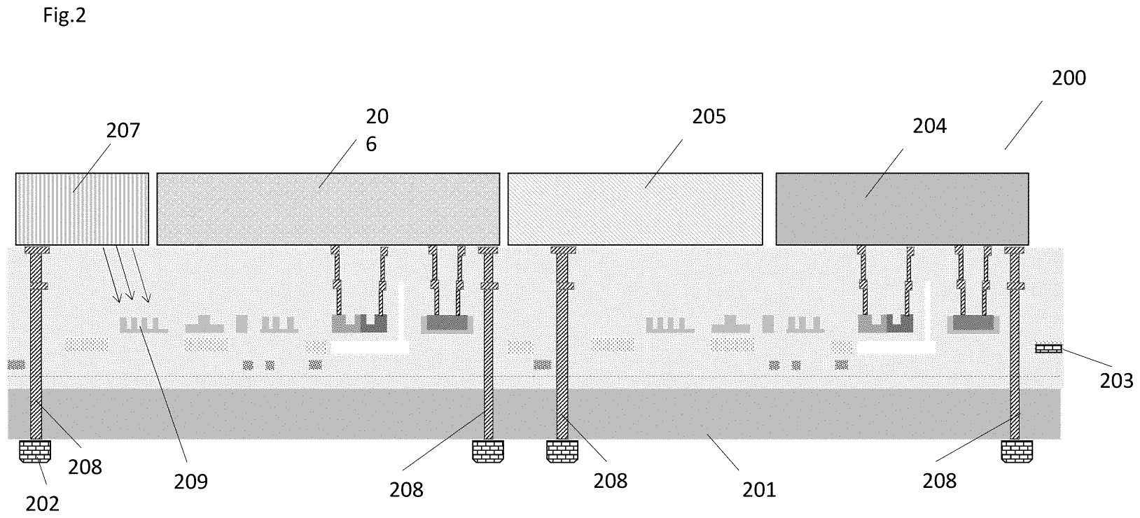

FIG. 2 shows an embodiment of an active photonic interposer with electronic chips and a light source of a laser diode, which are all flip chip boned on top the interposer. Schematically present here is an active optical interposer system 200 made of two devices shown in FIG. 1 to emphasis that the size of the interposer can be larger than lithographic step size if needed as there are cross step field waveguide features such as 124 and 131 shown in FIG. 1 within the layer(s) made of moderate refractive index material. As shown in FIG. 2, on top of the TSV structure at the back of the substrate 201, there are solder balls on top of the under bump metallization (UBM) representing here as 202 to electrically connect externally. There is also a edge coupler 203 to enable the system of 200 to connect to external optical fiber for data communication. At the front size interposer system, there are four chips flip-chip bonded on. They are chip 204, 205, 206, 207. It is schematically shown here that chips 204 and 206 connects with the modulator and photodetector (referred FIG. 1) to illustrate the fact that the data communication between the chips 204 and 206 is carried out by the optical waveguide built inside the active photonic interposer. Along with the optical fiber edge coupler 203, this active photonic interposer provides a huge optical bandwidth and fast data speed for both internal and external data communication without much heat generation. It is also worthwhile to note that the power suppy to the chip 204 and 206 all through the TSV structures 208. Chip 205 does not connect to modulator or photodiode, which means that it still uses Cu wire connections built in the interposer for data connection while its electric power is also provided by the TSV structure 208. Chp 207 represents a laser diode with its power from the TSV 208 to couple its emitting light to the grating coupler 209 to provide light source for the whole interposer system 200.

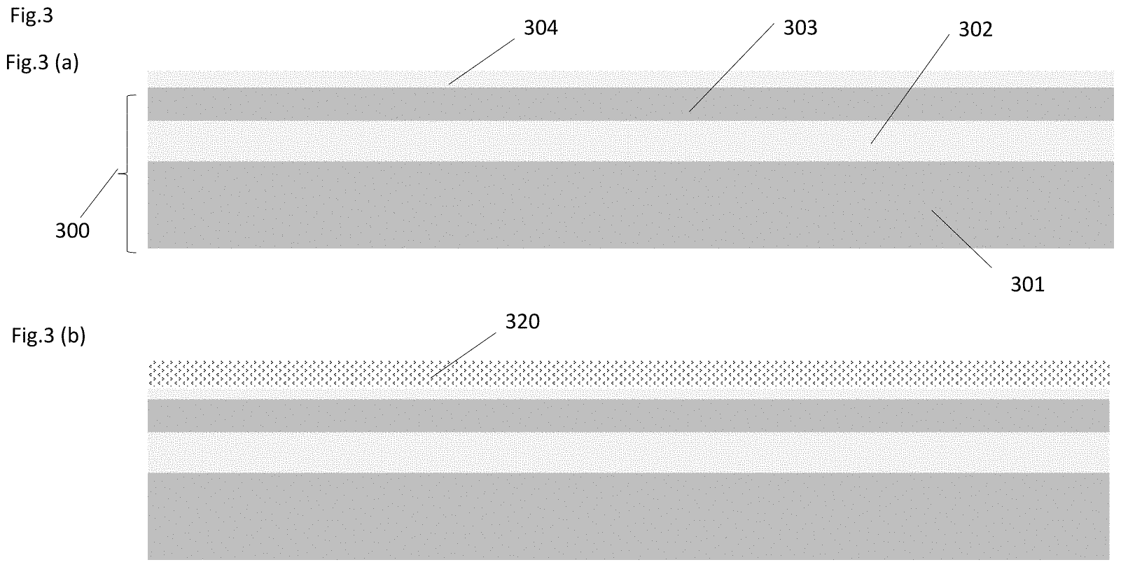

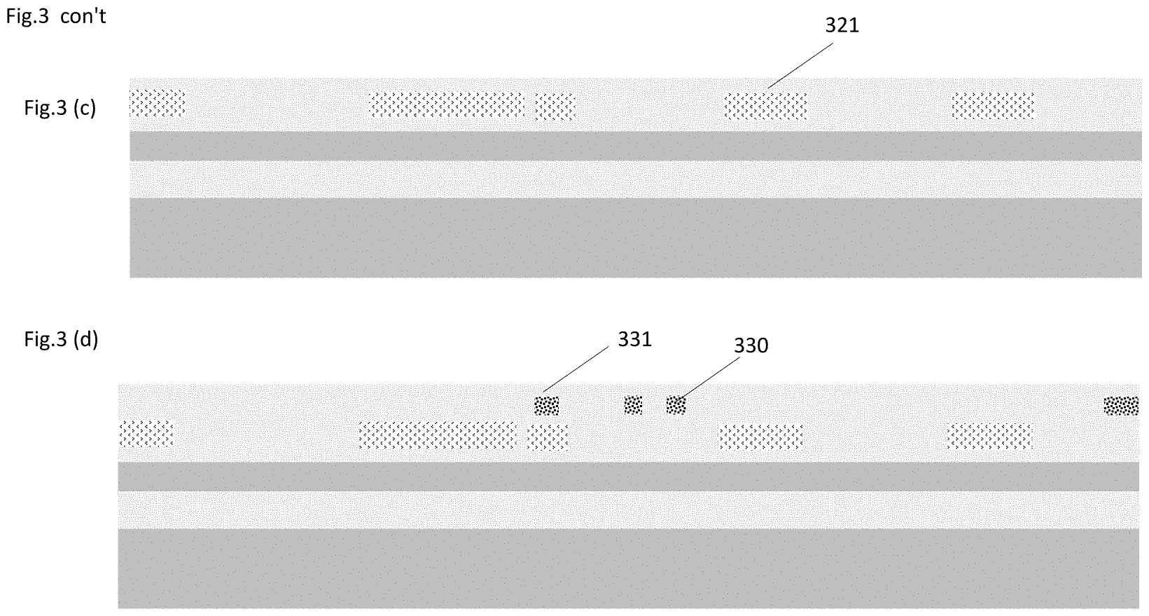

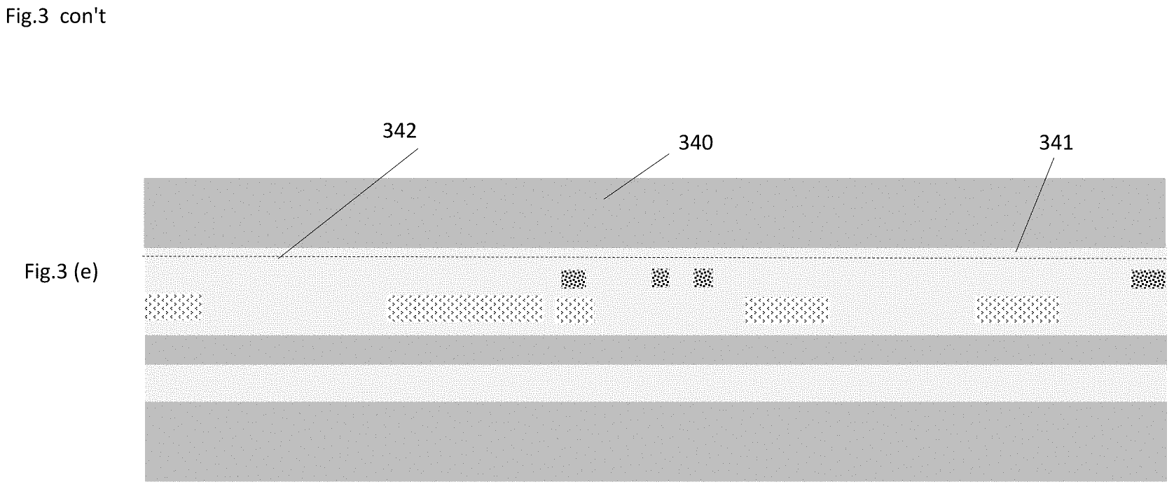

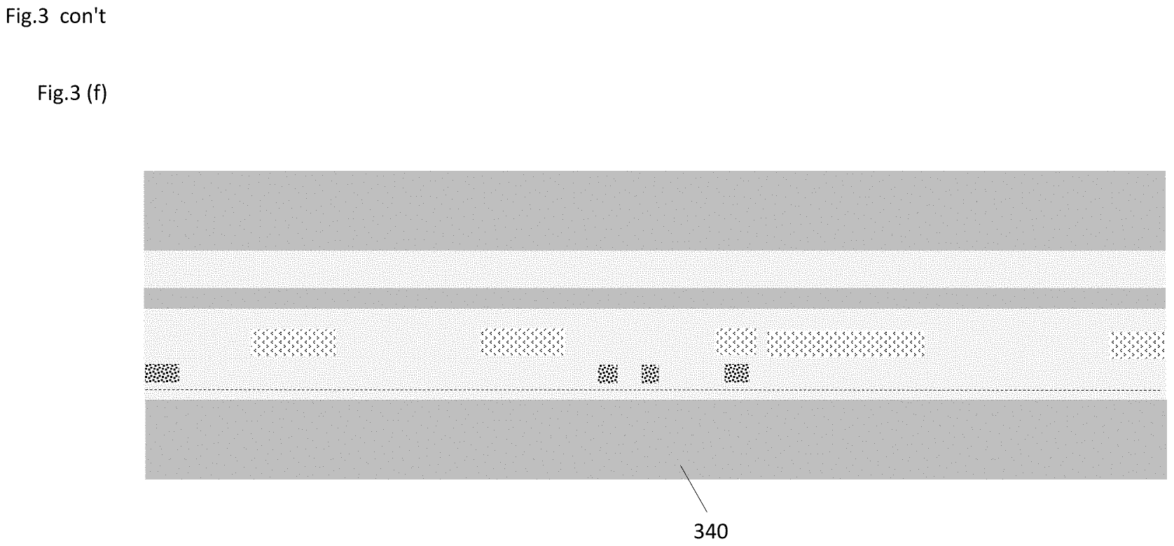

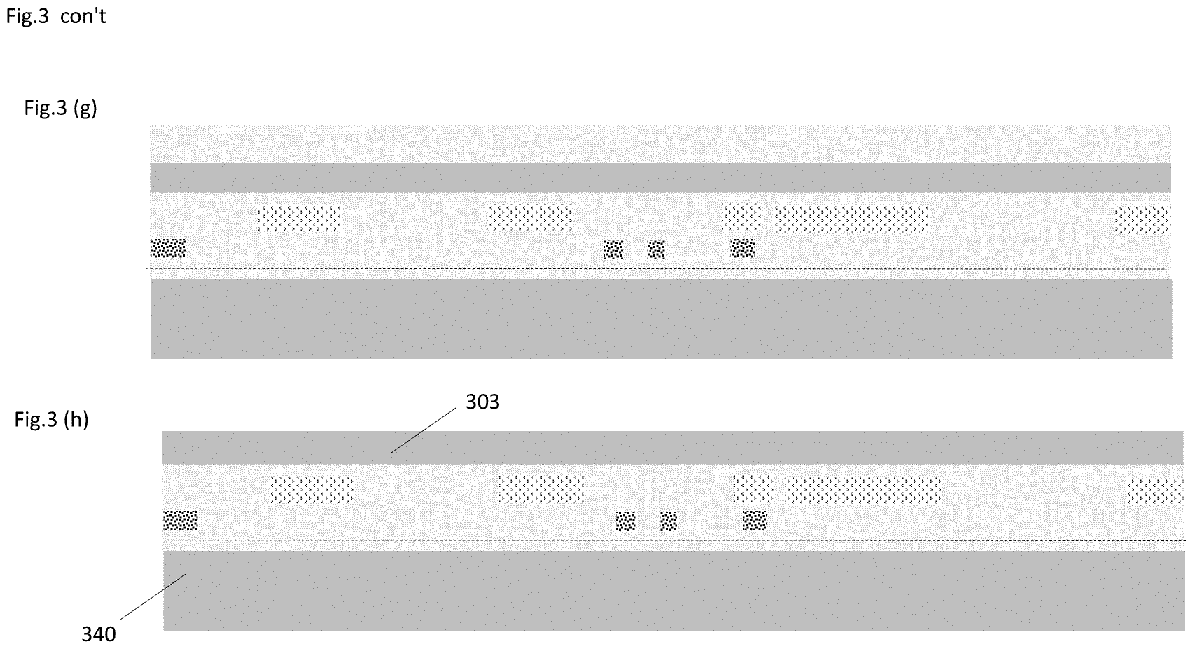

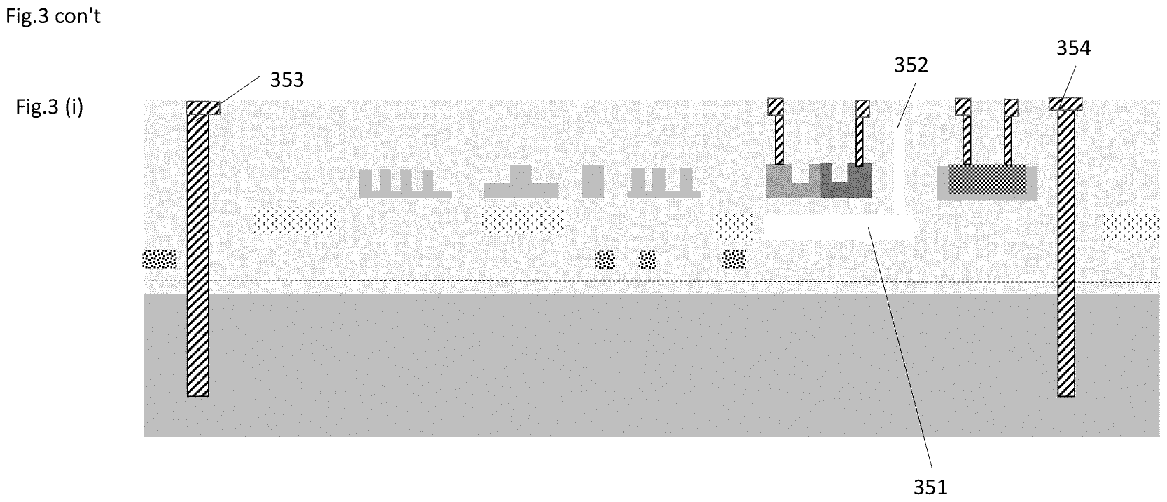

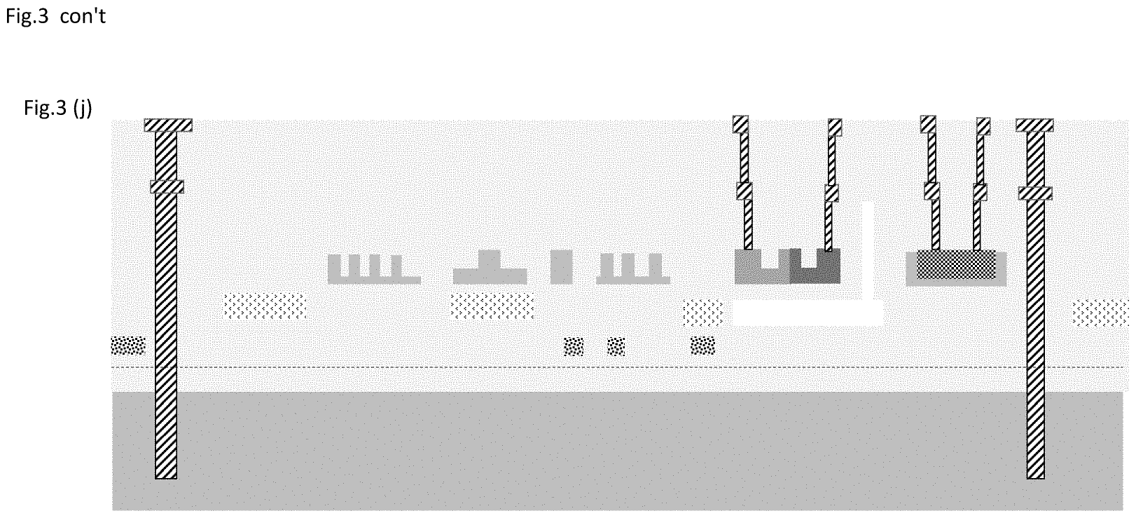

FIG. 3 (a)-(j) show an embodiment of a process flow to make the structure shown in FIG. 1 starting with a SOI wafer. FIG. 3(a) show the process flow starts from a SOI wafer 300 with its substrate 301, BOX layer 302 and SOI layer 303. A layer of SiO2 304 is formed on top of SOI layer 303. The layer 304 acts as the space layer between the SOI layer and subsequent layer of moderate refractive index material. In order to ensure the best interface between the SiO2 layer 304 and SOI layer 303, a thin thermal oxide can be grown first before a targeted thickness of SiO2 oxide is deposited on. To ensure less loss of the SOI thickness, the thermal grown SiO2 can not be too thick. FIG. 3(b) shows a layer of moderate refractive index material 310 is deposited on top of the oxide layer 304. Since there is no any thermal budget limitation during the deposition of layer 310 and subsequent thermal annealing (if needed), the quality of the materials 320 can be tuned stoichiometrically to ensure the best optical performance. FIG. 3(c) shows that the layer 320 is patterned with various optical building blocks to form a photonic circuitry followed by oxide backfill, wafer planarization, then deposition of an extra spacing layer 321, which separates the layer 320 from the subsequent another moderate refractive index material. It is worthwhile to point out the next moderate refractive index material may not be an necessary requirement. It all depends whether there is a need from designs to add on extra layers of moderate refractive index optical material or not. The reason why we introduce the extra layer of moderate refractive index material here is because we would like to illustrate the fact that the invented approach in this disclosure allows extra optical layers to be added on very flexibly. If really needed, extra single crystal Si layer can be bonded on top of the layer 320 either for purpose of forming either optical components or CMOS circuitry for electrical control, or even for the purpose of forming some microelectromechnical system MEMS devices.

FIG. 3(d) shows the schematic wafer cross section after layer 330 (shown as layer 130 in FIG. 1) is deposited, patterned, backfill with SiO2, flatten by CMP, then an extra SiO2 layer 331 is added on. FIG. 3(e) shows the final system substrate bonding process during wafer process flow. As shown, a Si wafer 340 with oxide layer 341 is boned on top of the finished wafer shown in FIG. 3(d) with the bonding interface represented by the dash line 342. The thickness of oxide layer 341 is predetermined to ensure that light propagates within the photonic circuitry in layer 330 will not leak to the system substrate 340. FIG. 3(f) is essentially the same as FIG. 3(e) only with the wafer upside down with the bonded Si wafer 340 at the bottom to allow subsequent wafer processes to continue.

FIG. 3(g) shows the schematic wafer cross section after the initial SOI wafer substrate 301 is removed with the BOX layer exposed. FIG. 3(h) shows the result after the BOX layer 302 is also removed. It is worthwhile to point out that the original SOI layer 303 is now at the front side of the wafer system. Sandwiched between the SOI layer 303 and bonded system substrate 340 is the two layers of moderate refractive index materials with necessary photonic circuitries being fabricated already in them as well as the light coupling features between the layers to allow light travelling between. All the oxide between the SOI layer 303 and bonded system substrate 340 can be regarded as ‘new’ BOX layer in the FIG. 3(h). From now on, all the previously matured SOI wafer process steps for Si photonic wafer can now be resumed to create various passive and active optical components in this single crystal SOI layer.

FIG. 3(i) shows the schematic wafer cross section after the CMOS compatible Si photonic wafer processes is done upto the middle of the metallic layer at backend of line (BEOL) processes with various photonic features have been created already on the wafer. It is also noted that some undercut features 351 is created by etching away the sacrificial structure with in the layer 320 via the etch path 352 during wafer build. The undercut features such as 351 shown here is for improving the performance of the optical building blocks. As shown the TSV middle process steps are added to enable the TSV structures 353, 354 built into the substrate. FIG. 3(j) shows the schematic wafer cross section after BEOL process steps are all finished, which is literally the same as what is being shown in FIG. 1 apart from substrate wafer thinning step to reveal the TSV structures.

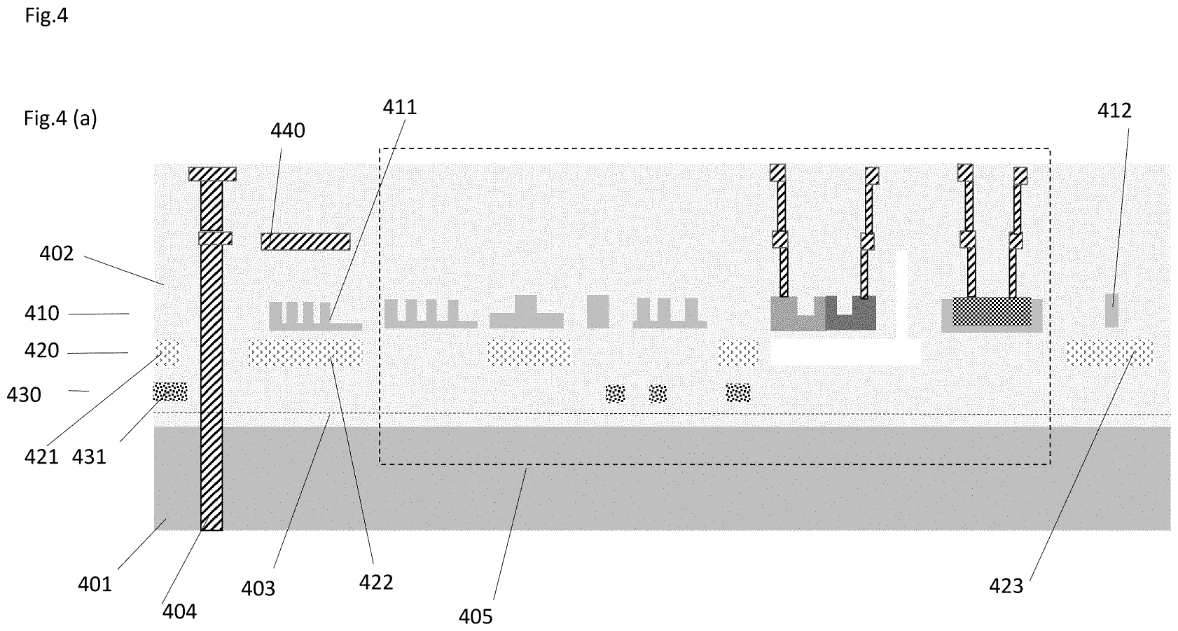

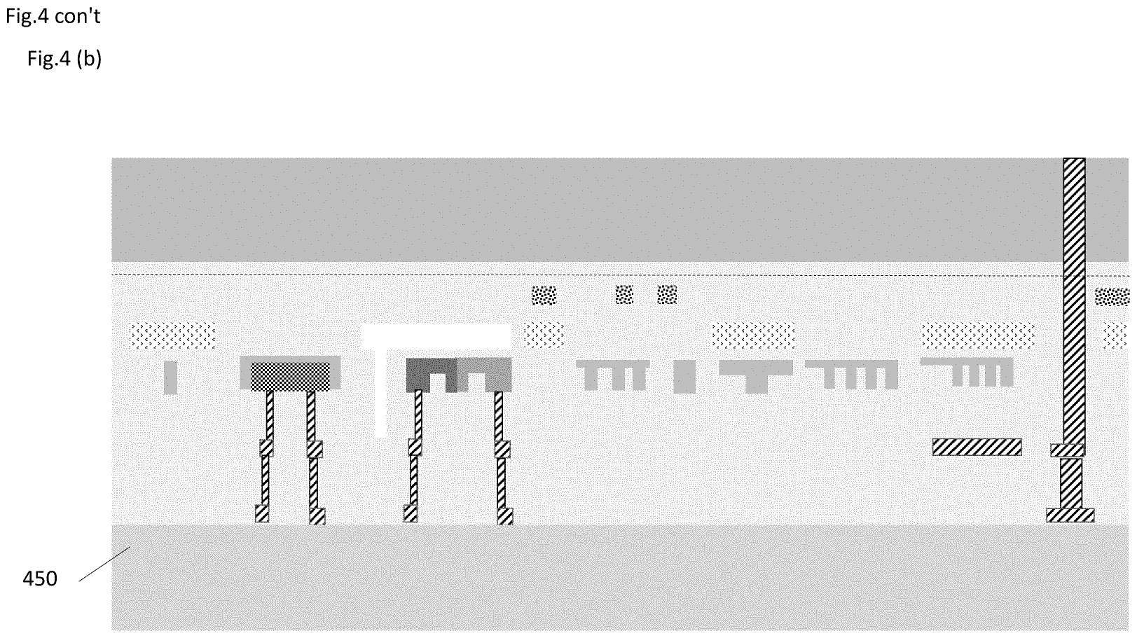

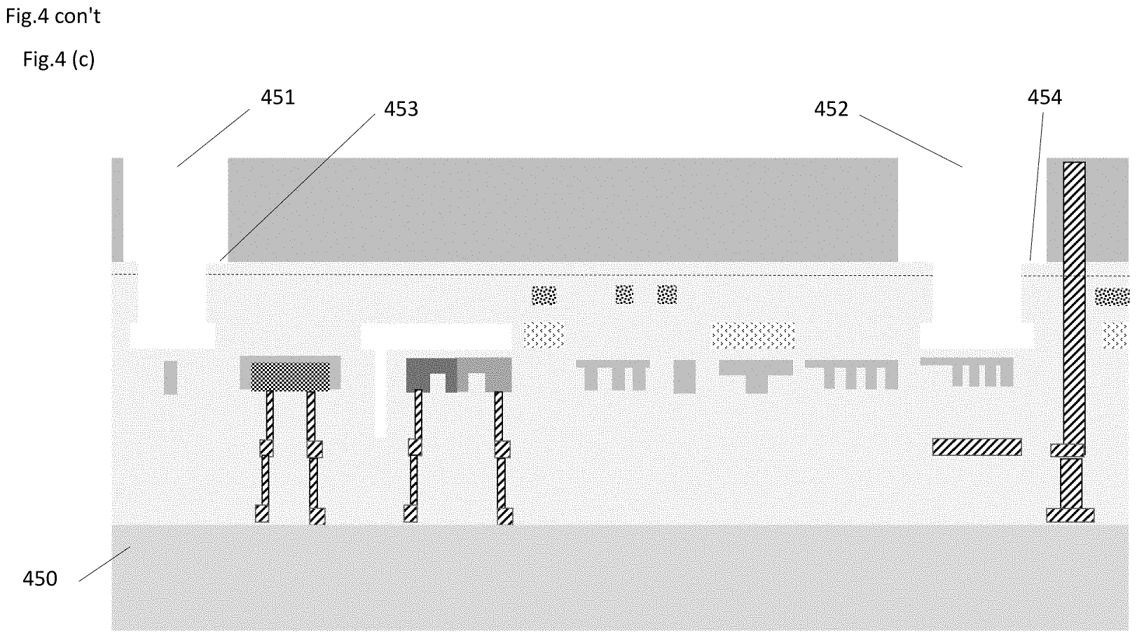

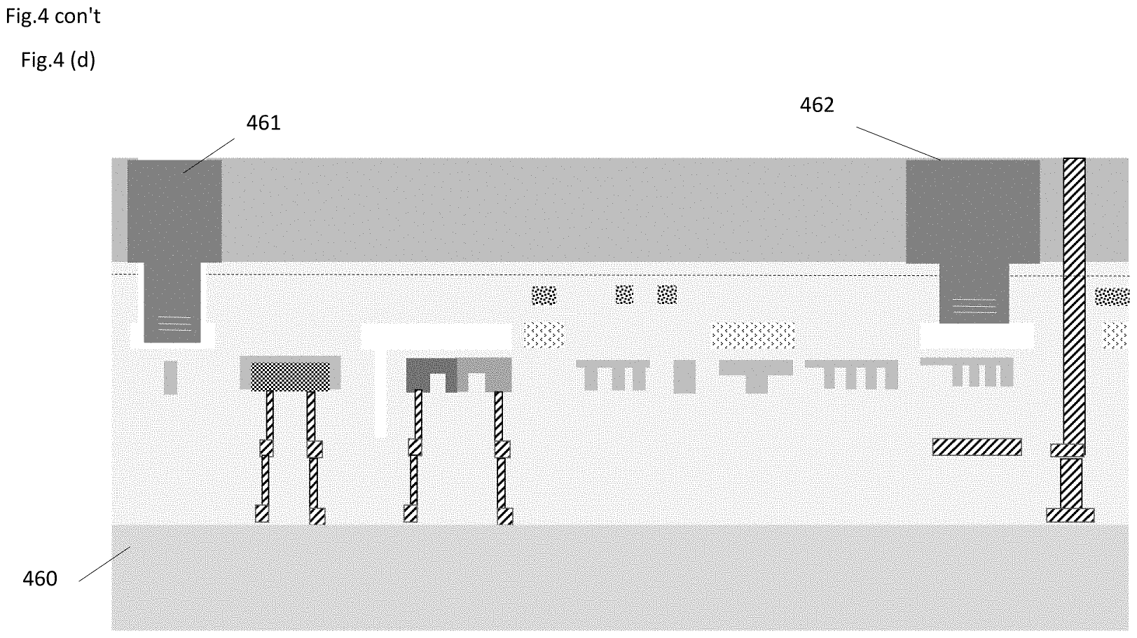

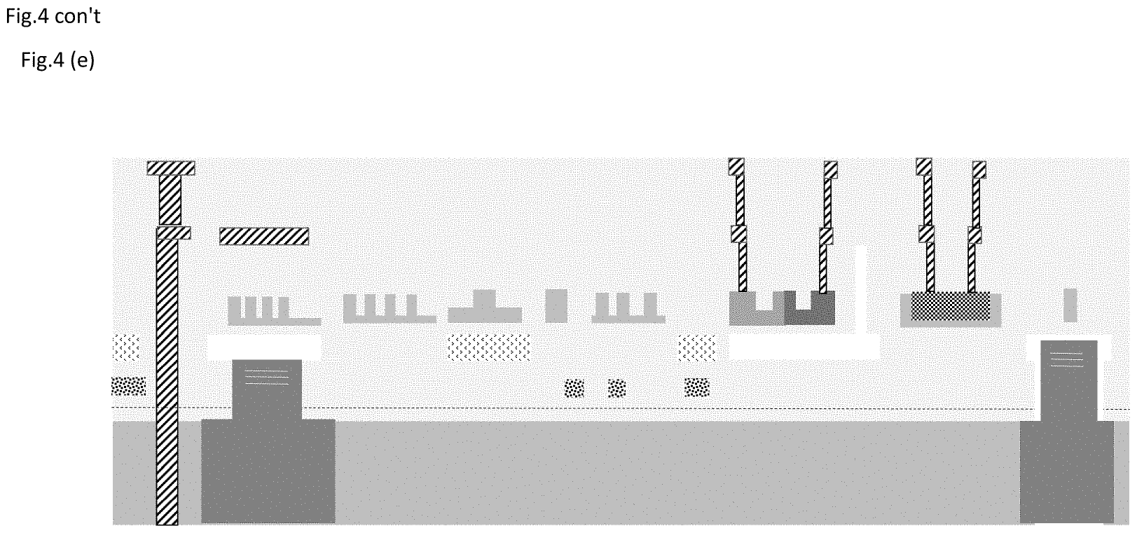

FIG. 4(a)-(e) shows an embodiment of a process flow to integrate IIIV light source either through grating coupling or evanescence coupling in the substrate of the proposed system. After wafer processes shown in FIG. 3(a)-(j) is done followed by TSV real, FIG. 4(a) is very much similar to what is shown in FIG. 1 with some additional features to underscore the integration of IIIV laser diode as light source for the proposed Si photonic platform. In details, FIG. 4(a) shows a thin-down substrate 401, over which there is SiO2 402 acting as cladding for various photonics circuitries. Substrate 401 is bonded together with 402 with a bonding interface 403. There is also TSV 404 through the substrate 401 which can provide electrical connections to the front side of the wafer. Three layers of photonic circuitries are built on wafer namely single crystal Si layer 410; the layer 420 of a moderate refractive index material; the layer 430 of another moderate refractive index material. Inside the dashline box 405, all the features have been shown in FIG. 1, therefore not extra details will be given here. Different from FIG. 1, there are some extra features shown in FIG. 4(a). They are an edge coupler or cross lithographic step field waveguide 421 (same as 124 in FIG. 1) in layer of 420 and a cross lithographic step field waveguide 431 (same as 131 in FIG. 1) in layer of the 430. More importantly, there are some additional features which are relevant to the proposed process flow in FIG. 4(a) to (e). They are the grating coupling structures for light incoming from a IIIV laser diode including a sacrificial structure 422 in layer 420, a grating 411, and an optional metal reflector 440, and evanescence coupling structure for light from a IIIV laser diode to a waveguide within Si layer including waveguide 412 and sacrificial feature 423. Although for the simplicity of drawing, the light coupling grating 411 and 412 is dawn here in layer 410, they can be inside layer 420 with sacrificial features in 430 by following the same process design principle shown here.

FIG. 4(b) shows that the incoming wafer of FIG. 4(a) is flipped upside down with a handling wafer or substrate 450 being temporarily boned on to expose the bottom side of the system shown in FIG. 4(a) for subsequent processing. FIG. 4(c) shows the end result after several lithographic and RIE process steps followed by an etch step to remove the sacrificial structures 422 and 423 to create the structures 451 and 452 for incoming laser diode placement places. It is worthwhile to mention that the steps 453 and 454 between the system substrate and SiO2, which acts as vertical positioning stop for the incoming insertion of IIIV laser diodes, are deliberately created. FIG. 4(d) shows the post insertion of a matching IIIV laser diodes 461 and 462 with the steps between system substrate and oxide as the vertical stop interface. In this particular case, laser diode 461 represents a edge emitting laser with light evanescence coupled into the waveguide while laser diode 462 illustrates either a vertical cavity surface emitting laser (VCSEL) or a edge emitting laser with an optical reflection plane for reflecting emitting light near vertically to couple into a grating structure below. The bonding of the laser diode 461 and 462 can be either a dielectric-to-dielectric bonding or an eutectic bonding, whose details are not shown in the schematic drawing. FIG. 4(e) shows the end result after the handling wafer/substrate is removed and the system is returned with system substrate at the bottom. As shown, we have a Si photonic system or an active Si photonic interposer with the built-in IIIV laser diodes acting as light sources embedded in the system substrate. The laser diodes can have its electrical connection to the external substrate or print circuitry board (PCB) easily although the laser diode's power connections are not shown here.

What is claimed is:

1. A material platform system for a photonic integrated circuitry comprises at least:
A light circuit made of a set of optical building blocks in a layer of a moderate refractive index material (named as a bottom layer), which is deposited and processed initially on top of a unprocessed SOI wafer composed of a silicon on insulator layer (named as a SOI layer), a buried oxide layer (named as a BOX layer) and a substrate;
A system substrate wafer which is bonded on said layer of a moderate refractive index material via a wafer-to-wafer bonding process;
A optical circuitry made of a set of devices fabricated in said SOI layer after said substrate and said BOX layer of said unprocessed SOI wafer are removed;
A set of light coupling structures to allow light traveling between the optical build blocks in the bottom layer and the devices in said SOI layer.

2. The system of claim 1, wherein said moderate refractive index material has its refractive index value smaller than that of said SOI layer with a minimal predetermined number in full optical spectrum.

3. The system of claim 1, wherein said material platform system further comprised at least a through silicon via (named as a TSV structure) to establish electric connection from the back to the front side of said material platform system.

4. The system of claim 1, wherein said material platform system has an extra light circuit made of a set of optical devices made in a layer of another moderate refractive index material, which is sandwiched between said bottom layer and said system substrate wafer but separated by a layer of SiO2 with a predetermined thickness.

5. The system of claim 1, wherein said set of optical building blocks in said bottom layer includes at least a device cross a pair of lithography step fields to extend the size of said photonic integrated circuitry beyond a lithography step field with minimal optical impact from a stitching error between the lithography step fields.

6. The system of claim 1, wherein said set of optical building blocks in said bottom layer has at least a sacrificial dummy feature, which is removable to leave a space for a III-V laser diode, whose light is coupled into the system via either an evanescence or a grating coupling.

7. The system of claim 6, where said III-V laser diode is bonded on the system from an open structure with at least a stop feature created on the system substrate wafer to control movement during a bonding process.

8. The system of claim 1, wherein said set of optical building blocks in said bottom layer has at least a sacrificial dummy feature, which is removed later to leave a undercut below a function device in said SOI layer to enhance its performance.

9. The system of claim 4, wherein said set of optical devices made in said layer of another moderate refractive index material has at least a sacrificial dummy feature, which is removable to leave a space for a bonded III-V laser diode, whose light is coupled into the system via either an evanescence or a grating coupling.

10. The system of claim 4, wherein said set of optical devices made in said layer of another moderate refractive index material has a light coupling structure to allow light traveling between this layer and the optical build blocks in the bottom layer.

11. The system of claim 1, wherein said material platform system is used as an active photonic interposer.

12. The system of the claim 11, wherein said active photonic interposer allows a set of chips, which are flip-chip bonded on top of the interposer, having an optical data connection via a light modulation and detection mechanism.

13. The system of the claim 11, wherein said active photonic interposer has a laser diode flip-chip bonded on to provide a light source for the system.

14. The system of the claim 1, wherein said moderate refractive index material is either Si3N4, or SiNO, or AlN, or diamond, or LiNbO3, or SiC, or Ta2O5, or TiO2, or As2S3, or high index doped SiO2 hydex, or their stacked material combinations i.e. one material layer on top of another material layer.

15. The system of the claim 1, wherein said moderate refractive index material is made of a trilayer material configured as A(t1)/SiO2(t2)/A(t2), where t1 is the thickness of a top layer made of material A, t2 is the thickness of a middle SiO2 layer thinner than half of the wavelength of a concerned optical wave in said light circuit in the bottom layer, t3 is the thickness of a bottom layer made of material A, in which A is either Si3N4, or SiNO, or AlN, or diamond, or LiNbO3, or SiC, or Ta2O5, or TiO2, or As2S3, or high index doped SiO2 hydex.

16. The system of the claim 1, wherein said moderate refractive index material is made of a trilayer material configured as A(t1)/SiO2(t2)/B(t2), where t1 is the thickness of a top layer made of material A, t2 is the thickness of a middle SiO2 layer thinner than half of the wavelength of a concerned optical wave in said light circuit in the bottom layer, t3 is the thickness of a bottom layer made of material B (different from material A), in which A and B is either Si3N4, or SiNO, or AlN, or diamond, or LiNbO3, or SiC, or Ta2O5, or TiO2, or As2S3, or high index doped SiO2 hydex.

17. The system of the claim 4, wherein said layer of another moderate refractive index material is a layer of either Si3N4, or SiNO, or AlN, or diamond, or LiNbO3, or SiC, or Ta2O5, or TiO2, or As2S3, or high index doped SiO2 hydex, or their stacked material combinations i.e. one material layer on top of another material layer.

18. The system of the claim 4, wherein said layer of another moderate refractive index material is made of a trilayer material configured as A(t1)/SiO2(t2)/A(t2), where t1 is the thickness of a top layer made of material A, t2 is the thickness of a middle SiO2 layer thinner than half of the wavelength of a concerned optical wave in said light circuit in the bottom layer, t3 is the thickness of a bottom layer made of material A, in which A is either Si3N4, or SiNO, or AlN, or diamond, or LiNbO3, or SiC, or Ta2O5, or TiO2, or As2S3, or high index doped SiO2 hydex.

19. The system of the claim 4, wherein said layer of another moderate refractive index material is made of a trilayer material configured as A(t1)/SiO₂(t2)/B(t2), where t1 is the thickness of a top layer made of material A, t2 is the thickness of a middle SiO2 layer thinner than half of the wavelength of a concerned optical wave in said light circuit in the bottom layer, t3 is the thickness of a bottom layer made of material B (different from material A), in which A and B is either Si3N4, or SiNO, or AlN, or diamond, or LiNbO3, or SiC, or Ta2O5, or TiO2, or As2S3, or high index doped SiO2 hydex.

20. The system of the claim 11, wherein said active photonic interposer is used to built a photonic and electronic mixed (or hybrid) neural network.
